(19) United States
(12) Patent Application Publication
(10) Pub. No.: US 2025/0071903 A1
(43) Pub. Date: Feb. 27, 2025

(54) METHOD FOR EFFICIENTLY CONNECTING MANY HIGH DENSITY SMT PCB/BACKPLANE CONNECTORS FOR GREATEST PCB EDGE EFFICIENCY

(71) Applicant: Samsung Electronics Co., Ltd., Suwon-si (KR)

(72) Inventor: Casey Glenn Thielen, Chandler, AZ (US)

(21) Appl. No.: 18/421,196

(22) Filed: Jan. 24, 2024

Related U.S. Application Data
(60) Provisional application No. 63/533,850, filed on Aug. 21, 2023.

(51) Int. Cl. H05K 1/18; H05K 1/11

(52) U.S. Cl. CPC H05K 1/181; H05K 1/117; H05K 2201/10189

(57) ABSTRACT

A system includes a printed circuit board having high-density interconnects, a number of surface mount connectors coupled to an edge portion of the printed circuit board, and at least one fastener securing the connectors to the printed circuit board. Each surface mount connector includes a number of outriggers. A first connector and a second connector are interlocked on a first side of the printed circuit board. A third connector and a fourth connector are interlocked on a second side of the printed circuit board opposite to the first and second connectors on the first side of the printed circuit board.

### CROSS-REFERENCE TO RELATED APPLICATION(S)

The present application claims priority to and the benefit of U.S. Provisional Application No. 63/533,850, filed Aug. 21, 2023, the entire content of which is incorporated herein by reference.

### BACKGROUND

### 1. Field

The present application relates to electrical connectors configured to connect to a printed circuit board.

### 2. Description of the Related Art

Computer racks house a number of printed circuit boards (PCBs), and the PCBs are connected together with cabling that is connected to connectors on the PCBs. As the speed of the signals through the cabling between the PCBs increases to high-speed IOs (e.g., 64 GT/s), the connectors are transitioning from press-fit type connectors (in which pins on the connectors are press-fit into physical holes in the PCB) to surface mount type connectors (in which pads on the connectors are soldered to corresponding pads on the PCB) or compression connectors as another surface mounted option. However, typical surface mount type connectors may not provide sufficient mechanical stability between the connector and the PCB to facilitate connecting and disconnecting the cables from the connectors. Alternatively, these typical surface mount connectors may utilize excessive space on the PCB to achieve a stable mechanical connection, which limits the number of connectors that can fit along the edge (i.e., the “shoreline”) of the PCB and thus limits the number of serializer/deserializer (SerDes) signals that can be brought off of the PCB.

The above information disclosed in this Background section is only for enhancement of understanding of the background of the invention and therefore it may contain information that does not constitute prior art.

### SUMMARY

The present disclosure relates to various embodiments of an electrical connector configured to be connected to a printed circuit board (PCB). In one embodiment, the electrical connector includes a housing, a number of pins or receptacles in the housing, and a number of outriggers coupled to the housing. A first pair of the outriggers along a first side of the housing is higher than a second pair of the outriggers along a second side of the housing.

The second pair of outriggers may be substantially flush with a lower surface of the housing, and the first pair of outriggers may be spaced apart from the lower surface by a gap.

A height of the gap may be substantially equal to a thickness of each of the second pair of outriggers.

The outriggers may be at corners of the housing.

The electrical connector may include a number of pads on a lower surface of the housing.

The present disclosure also relates to various embodiments of a computer assembly. In one embodiment, the computer assembly includes a printed circuit board (PCB) including high-density interconnects, a number of surface mount electrical connectors coupled to an edge portion of the printed circuit board, and at least one fastener securing the surface mount electrical connectors to the printed circuit board. Each surface mount electrical connector includes a number of outriggers and a number of IO pads. A first surface mount electrical connector and a second surface mount electrical connector interlocked on a first side of the printed circuit board. A third surface mount electrical connector and a fourth surface mount electrical connector are interlocked on a second side of the printed circuit board opposite to the first and second surface mount electrical connectors on the first side of the printed circuit board.

The at least one fastener may extend through an outrigger of each of the first surface mount electrical connector, the second surface mount electrical connector, the third surface mount electrical connector, and the fourth surface mount electrical connector, and the at least one fastener may compress the IO pads of the first surface mount electrical connector, the second surface mount electrical connector, the third surface mount electrical connector, and the fourth surface mount electrical connector against the high-density interconnects of the printed circuit board.

The fastener may be a retained fastener.

A portion of each of the first surface mount electrical connector, the second surface mount electrical connector, the third surface mount electrical connector, and the fourth surface mount electrical connector may overhang the edge portion of the printed circuit board.

A pair of front outriggers of each surface mount electrical connector may overhang the edge portion of the printed circuit board.

Each of the outriggers may be on the printed circuit board.

The outriggers may include a first pair of outriggers at a first side of the connector and a second pair of outriggers at a second side of the connector opposite to the first side, and the first pair of outriggers may be higher than the second pair of outriggers.

The second pair of outriggers may be substantially flush with a lower surface of the connector, and the first pair of outriggers may be spaced apart from the lower surface of the connector.

The present disclosure also relates to various methods of installing two or more electrical connectors on a printed circuit board. In one embodiment, the method includes positioning a first electrical connector and a second electrical connector on a first side of the printed circuit board and along an edge portion of the printed circuit board such that a pair of outriggers of the first electrical connector overlap a pair of outriggers of the second electrical connector. The method also includes positioning a third electrical connector and a fourth electrical connector on a second side of the printed circuit board opposite to the first side of the printed circuit board such that a pair of outriggers of the third electrical connector overlap a pair of outriggers of the fourth electrical connector. The method further includes compressing the first electrical connector, the second electrical connector, the third electrical connector, and the fourth electrical connector against the printed circuit board by inserting fasteners through aligned openings in the pair of outriggers in each of the first electrical connector, the second electrical connector, the third electrical connector, and the fourth electrical connector.

This summary is provided to introduce a selection of features and concepts of embodiments of the present disclosure that are further described below in the detailed description. This summary is not intended to identify key or essential features of the claimed subject matter, nor is it intended to be used in limiting the scope of the claimed subject matter. One or more of the described features may be combined with one or more other described features to provide a workable system or method.

### BRIEF DESCRIPTION OF THE DRAWINGS

The features and advantages of embodiments of the present disclosure will be better understood by reference to the following detailed description when considered in conjunction with the drawings. The drawings are not necessarily drawn to scale.

FIGS. 1A-1D are a front perspective view, a top view, a side view, and a front view, respectively, of a series of electrical connectors according to one embodiment of the present disclosure connected to a printed circuit board (PCB); and

FIG. 2 is a flowchart illustrating tasks of a method of attaching electrical connectors to a printed circuit board according to one embodiment of the present disclosure.

### DETAILED DESCRIPTION

The present disclosure relates to various embodiments of a surface mount type electrical connector configured to be connected to a printed circuit board (PCB) having high-density interconnects. Additionally, the electrical connectors include outriggers that are configured to provide sufficient mechanical stability to the electrical connectors on the PCB while also minimizing or at least reducing the amount of space that is required on the PCB (i.e., electrical connectors are configured to enable high-density placement of a number of electrical connectors on the PCB and to also provide mechanical stability for the electrical connectors on the PCB, which enables cables connected to the electrical connectors to be repeatedly attached and detached without damaging the electrical connectors or the PCB). Additionally, the electrical connectors may be placed on top and bottom of the PCB (i.e., in a “belly-to-belly” configuration) which enables using common connection point(s) (e.g., fasteners such as retention pins) to compress the electrical connectors against the PCB such that the PCB is sandwiched between the electrical connectors.

Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

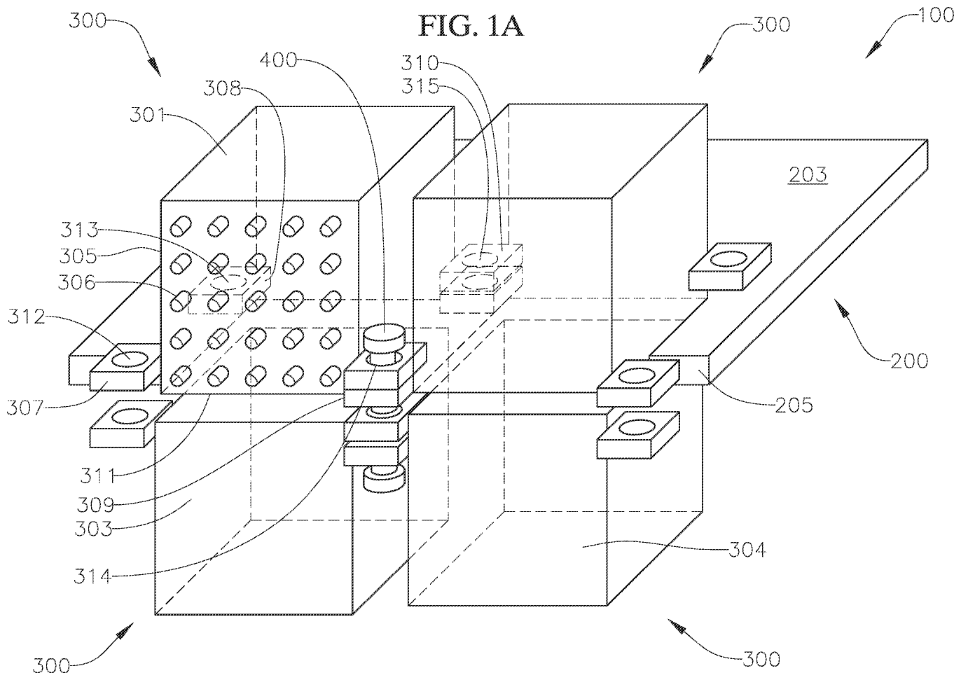

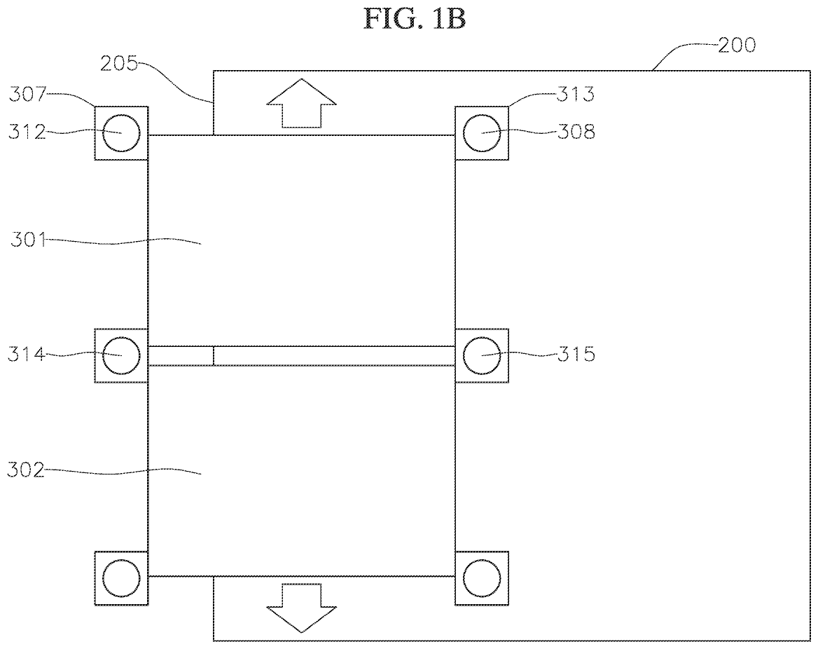

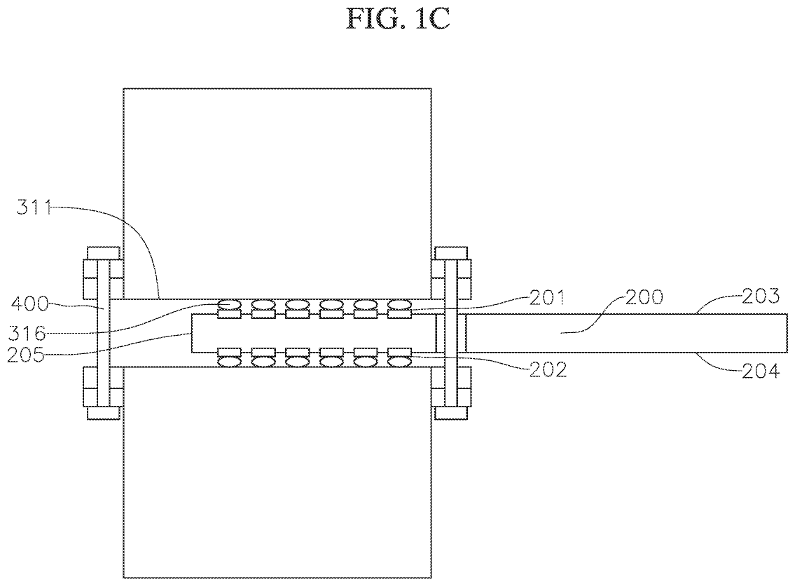

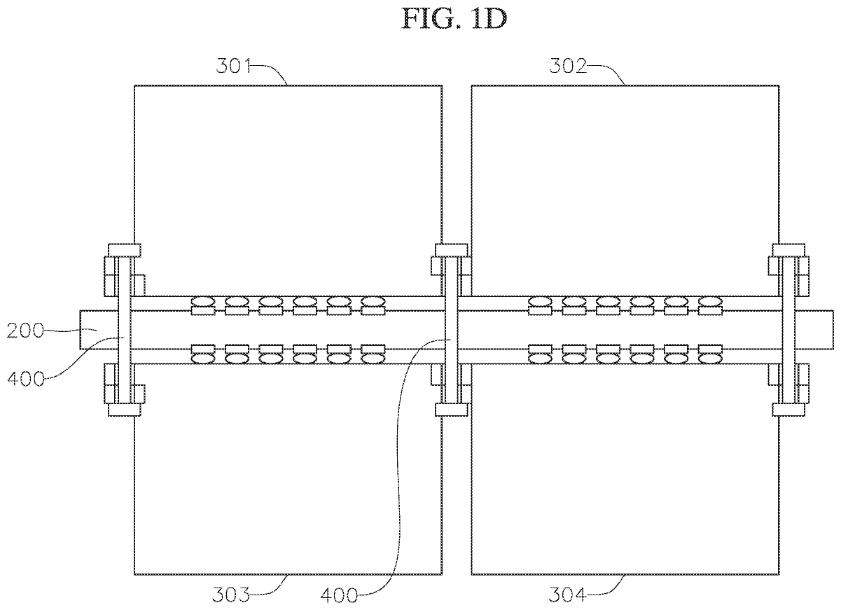

With reference now FIGS. 1A-1D, a system 100 according to one embodiment of the present disclosure includes a printed circuit board (PCB) 200 and a number of electrical connectors 300 coupled to the PCB 200. In one or more embodiments, the PCB 200 may be a high-density interconnect (HDI) PCB including a number of IO pads 201, 202 on a first surface (e.g., an upper surface) 203 and a second surface (e.g., a lower surface) 204, respectively, of the PCB 200.

In the illustrated embodiment, the system 100 includes a first electrical connector 301 and a second electrical connector 302 on the first surface (e.g., the upper surface) 203 of the PCB 200, and a third electrical connector 303 and a fourth electrical connector 304 on the second surface (e.g., the lower surface) 204 of the PCB 200. In the illustrated embodiment, the first and second connectors 301, 302 are interlocked with each other, and the third and fourth connectors 303, 304 are interlocked with each other and aligned (e.g., vertically aligned) with the first and second connectors 301, 302, respectively, in a “belly-to-belly” configuration. Furthermore, in the illustrated embodiment, the first, second, third, and fourth electrical connectors 301-304 are provided along an edge (or edge portion) 205 of the PCB 200 (i.e., the first, second, third, and fourth electrical connectors 301-304 are provided along the “shoreline” of the PCB 200).

In the illustrated embodiment, each of the electrical connectors 301-304 may have the same (or substantially the same) configuration. In the illustrated embodiment, each electrical connector 301-304 includes a housing 305, pins or receptacles 306 in the housing 305 (depending on whether the electrical connector 301-304 is a male or female connector), and a plurality of outriggers 307, 308, 309, 310 coupled to the housing 305. In the illustrated embodiment, each electrical connector 301-304 includes a first pair of outriggers 307, 308 at a first side of the housing 305 and a second pair of outriggers 309, 310 at a second side of the housing 305. Additionally, in the illustrated embodiment, the first pair of outriggers 307, 308 are higher on the housing 305 than the second pair of outriggers 309, 310. For example, in one or more embodiments, the second pair of outriggers 309, 310 may be flush or substantially flush with a lower surface (e.g., a bottom surface) 311 of the housing 305 and the first pair of outriggers 307, 308 may be spaced apart from the lower surface 311 of the housing 305 by a gap. Additionally, in one or more embodiments, the height of the gap (i.e., the distance between the lower surface 311 of the housing 305 and the lower surface of the first pair of outriggers 307, 308 may be equal (or substantially equal) to the thickness of the second pair of outriggers 309, 310. In one or more embodiments, the outriggers 307, 308, 309, 310 may be at or proximate to corners of the housing 305. In the illustrated embodiment, each of the outriggers 307, 308, 309, 310 has a square shape, although in one or more embodiments, the outriggers 307, 308, 309, 310 may have any other suitable shape or shapes. Additionally, in the illustrated embodiment, each of the outriggers 307, 308, 309, 310 includes an opening (e.g., a through-hole) 312, 313, 314, 315, respectively, configured to accommodate a fastener securing the outriggers 307, 308, 309, 310 to the PCB 200. In one or more embodiments, the outriggers in the first pair of outriggers 307, 308 may be at different heights on the housing 305 (e.g., the outrigger 307 may be higher than the outrigger 308, or the outrigger 308 may be higher than the outrigger 307). Similarly, in one or more embodiments, the outriggers in the second pair of outriggers 309, 310 may be at different heights on the housing 305 (e.g., the outrigger 309 may be higher than the outrigger 310, or the outrigger 310 may be higher than the outrigger 309). For instance, in one or more embodiments, one outrigger of the first pair of outriggers 307, 308 may be flush or substantially flush with the lower surface 311 of the housing 305 and the other outrigger of the first pair of outriggers 307, 308 may be spaced apart from the lower surface 311 of the housing 305 by a gap. Additionally, in one or more embodiments, one outrigger of the second pair of outriggers 309, 310 may be flush or substantially flush with the lower surface 311 of the housing 305 and the other outrigger of the second pair of outriggers 309, 310 may be spaced apart from the lower surface 311 of the housing 305 by a gap. In one or more embodiments, the outriggers 307, 308, 309, 310 may have a thickness in a range from approximately ⅛ inch to approximately ⅜ inch, and the gap between the lower surface 311 of the housing 305 and the lower surface of the outriggers 307, 308, 309, 310 that are spaced apart from the lower surface 311 of the housing 305 may be in a range from approximately ⅛ inch to approximately ⅜ inch. That is, in one or more embodiments, the gap between the lower surface 311 of the housing 305 and the outriggers 307, 308, 309, 310 that are spaced apart from the lower surface 311 of the housing 305 may be equal or substantially equal to the nominal thickness of the outriggers 307, 308, 309, 310 (i.e., the gap may be equal or substantially equal to the thickness of the outriggers 307, 308, 309, 310 plus a manufacturing tolerance).

In the illustrated embodiment, each of the electrical connector 301-304 includes a series of IO pads 316 on the lower surface (e.g., a bottom surface) 311 of the housing 305 that are configured to contact the corresponding IO pads 201, 202 on the first surface (e.g., an upper surface) 203 and the second surface (e.g., a lower surface) 204, respectively, of the PCB 200. Accordingly, in the illustrated embodiment, the electrical connector 301-304 are surface mount (SMT) connectors configured to be connected to the IO pads 201, 202 of the PCB 200.

In the illustrated embodiment, when the first and second connectors 301, 302 are connected to the PCB 200, the second pair of outriggers 309, 310 of the first connector 301 overlap the first pair of outriggers 307, 308 of the second connector 302 and the first pair of outriggers 307, 308 of the second connector 302 extend into the gap separating the second pair of outriggers 309, 310 of the first connector 301 from the lower surface 311 of the housing 305. In one or more embodiments, lower surfaces of the second pair of outriggers 309, 310 of the first connector 301 may contact (e.g., directly contact) upper surfaces of the first pair of outriggers 307, 308 of the second connector 302. Additionally, in the illustrated embodiment, the openings (e.g., holes) 314, 315 in the second pair of outriggers 309, 310 of the first connector 301 are aligned (or substantially aligned) with the openings (e.g., holes) 312, 313 in the first pair of outriggers 307, 308 of the second connector 302.

In the illustrated embodiment, when the third and fourth connectors 303, 304 are connected to the PCB 200, the second pair of outriggers 309, 310 of the fourth connector 304 overlap the first pair of outriggers 307, 308 of the third connector 303 and the first pair of outriggers 307, 308 of the fourth connector 304 extend into the gap separating the second pair of outriggers 309, 310 of the third connector 303 from the lower surface 311 of the housing 305. In one or more embodiments, lower surfaces of the second pair of outriggers 309, 310 of the fourth connector 304 may contact (e.g., directly contact) upper surfaces of the first pair of outriggers 307, 308 of the third connector 303. Additionally, in the illustrated embodiment, the openings (e.g., holes) 314, 315 in the second pair of outriggers 309, 310 of the fourth connector 304 are aligned with the openings (e.g., holes) 312, 313 in the first pair of outriggers 307, 308 of the third connector 303.

Additionally, in the illustrated embodiment, the second pair of outriggers 309, 310 of the first connector 301 and the first pair of outriggers 307, 308 of the second connector 302 are aligned with the second pair of outriggers 309, 310 of the fourth connector 304 and the first pair of outriggers 307, 308 of the third connector 303. Accordingly, in the illustrated embodiment, the openings (e.g., holes) 312, 313, 314, 315 in the first pair of outriggers 307, 308 of the second connector 302 and the second pair of outriggers 309, 310 of the first connector 301 and are aligned (or substantially aligned) (e.g., co-axial or substantially co-axial) with the openings (e.g., holes) 312, 313, 314, 315 in the first pair of outriggers 307, 308 of the third connector 303 and the second pair of outriggers 309, 310 of the fourth connector 304.

Additionally, in the illustrated embodiment, the system 100 includes fasteners (e.g., retention pins or screws) 400 extending through the aligned openings 312, 313, 314, 315 in the outriggers 307-310 of the first, second, third, and fourth electrical connectors 301-304. The fasteners compress the IO pads 316 of the electrical connectors 301-304 against the corresponding pads 201, 202 on the PCB 200 to form a compression connection between the electrical connectors 301-304 and the PCB 200.

In one or more embodiments, a portion of each of the electrical connectors 301-304 may overhang the edge 205 of the PCB 200 (i.e., a portion of each of the electrical connectors 301-304 may extend beyond the edge 205 such that a portion of each of the electrical connectors 301-304 is not on (above or below) the PCB 200). In the illustrated embodiment, the outriggers 307 and 309 (and the corresponding openings 312, 314 in the outriggers 307, 309) along the front edge of each electrical connector 301-304 overhang the edge 205 of the PCB 200. In one or more embodiments in which the front outriggers 307 and 309 overhang the edge 205 of the PCB 200, one of the front outriggers 307, 309 may extend below the lower surface 311 of the housing 305 (e.g., the lower one of the front outriggers 307, 309 may extend below the lower surface 311 of the housing 305). For example, in one or more embodiments, one of the front outriggers 307, 309 of each of the first and second connectors 301, 302 on the first surface (e.g., the upper surface) 203 of the PCB 200 may extend below the first surface 203 of the PCB 200 and one of the front outriggers 307, 309 of each of the third and fourth connectors 301, 302 on the second surface (e.g., the lower surface) 204 of the PCB 200 may extend above the second surface 204 of the PCB 200. In the illustrated embodiment, the PCB 200 includes openings to accommodate the fasteners 400 securing the rear outriggers of the first, second, third, and fourth electrical connectors 301-304 to the PCB 200, but the PCB 200 does not include openings to accommodate the fasteners 400 securing the front outriggers of the first, second, third, and fourth electrical connectors 301-304. Accordingly, positioning the front outriggers 307 and 309 (and the corresponding openings 312, 314 in the outriggers 307, 309) off of the edge 205 of the PCB 200 reduces the number of openings that must be provided in the PCB 200 to accommodate the fasteners 400 securing the electrical connectors 301-304 to the PCB 200. However, in one or more embodiments, the front outriggers 307 and 309 (and the corresponding openings 312, 314 in the outriggers 307, 309) may be positioned on the PCB 200 to increase the mechanical strength of the connection between the electrical connectors 301-304 and the PCB 200, which may enable the electrical connectors 301-304 to withstand greater mating/demating forces applied to connect/disconnect cables from the electrical connectors 301-304.

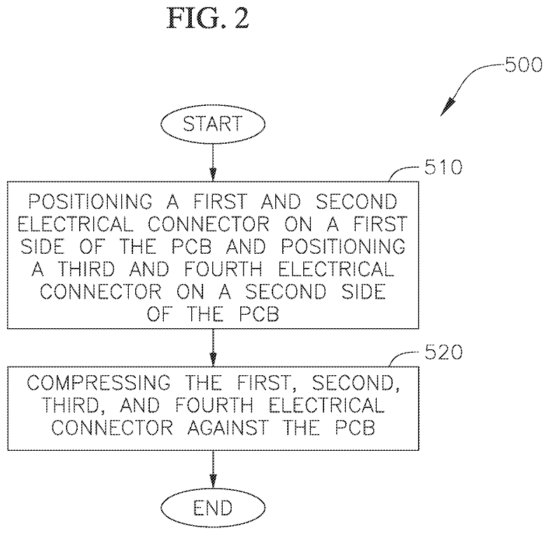

FIG. 2 is a flowchart illustrating tasks of a method 500 of attaching electrical connectors to a printed circuit board according to one embodiment of the present disclosure. The electrical connectors may be the same as or similar to the embodiment of the electrical connectors 301-304 illustrated in FIGS. 1A-1C. In the illustrated embodiment, the method 500 includes a task 510 of positioning a first electrical connector and a second electrical connector on a first side of the printed circuit board and positioning a third electrical connector and a fourth electrical connector of the plurality of electrical connectors on a second side of the printed circuit board opposite to the first side of the printed circuit board. Following the task 510, a pair of outriggers of the first electrical connector overlap a pair of outriggers of the second electrical connector, and a pair of outriggers of the third electrical connector overlap a pair of outriggers of the fourth electrical connector (i.e., the first and second electrical connectors are interlocked, and the third and fourth electrical connectors are interlocked). Additionally, following the task 510, the third and fourth electrical connectors are opposite to the first and second connectors, respectively (i.e., the first and second electrical connectors and the third and fourth connectors are arranged in a belly-to-belly configuration).

In the illustrated embodiment, the method 500 also includes a task 520 of compressing the first electrical connector, the second electrical connector, the third electrical connector, and the fourth electrical connector against the printed circuit board such that IO pads on the electrical connectors are compressed against corresponding pads on the printed circuit board. In one or more embodiments, the task 520 includes inserting fasteners (e.g., retained fasteners) through aligned openings in the pair of outriggers in each of the first electrical connector, the second electrical connector, the third electrical connector, and the fourth electrical connector.

While this invention has been described in detail with particular references to exemplary embodiments thereof, the exemplary embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims.

What is claimed is:

1. An electrical connector configured to be coupled to a printed circuit board, the electrical connector comprising:
a housing;
a plurality of pads on a lower surface of the housing;
a plurality of pins or receptacles in the housing; and
a plurality of outriggers coupled to the housing, wherein at least two of the plurality of outriggers are at different heights on the housing.

2. The electrical connector of claim 1, wherein a first pair of outriggers of the plurality of outriggers along a first side of the housing is higher than a second pair of outriggers of the plurality of outriggers along a second side of the housing.

3. The electrical connector of claim 2, wherein the second pair of outriggers are substantially flush with a lower surface of the housing, and wherein the first pair of outriggers are spaced apart from the lower surface by a gap.

4. The electrical connector of claim 3, wherein a height of the gap is substantially equal to a thickness of each of the second pair of outriggers.

5. The electrical connector of claim 1, wherein a first pair of outriggers of the plurality of outriggers along a first side of the housing are at different heights on the housing, and wherein a second pair of outriggers of the plurality of outriggers along a second side of the housing are at different heights on the housing.

6. A computer assembly comprising:
a printed circuit board (PCB) comprising high-density interconnects;
a plurality of surface mount electrical connectors coupled to an edge portion of the printed circuit board, each surface mount electrical connector of the plurality of surface mount electrical connectors comprising a housing, a plurality of outriggers, and a plurality of IO pads; and
at least one fastener securing the plurality of surface mount electrical connectors to the printed circuit board,
wherein a first surface mount electrical connector and a second surface mount electrical connector of the plurality of surface mount electrical connectors are interlocked on a first side of the printed circuit board,
wherein a third surface mount electrical connector and a fourth surface mount electrical connector of the plurality of surface mount electrical connectors are interlocked on a second side of the printed circuit board opposite to the first and second surface mount electrical connectors on the first side of the printed circuit board.

7. The computer assembly of claim 6, wherein the at least one fastener extends through an outrigger of each of the first surface mount electrical connector, the second surface mount electrical connector, the third surface mount electrical connector, and the fourth surface mount electrical connector, and
wherein the at least one fastener compresses the plurality of IO pads of the first surface mount electrical connector, the second surface mount electrical connector, the third surface mount electrical connector, and the fourth surface mount electrical connector against the high-density interconnects of the printed circuit board.

8. The computer assembly of claim 6, wherein a portion of each of the first surface mount electrical connector, the second surface mount electrical connector, the third surface mount electrical connector, and the fourth surface mount electrical connector overhang the edge portion of the printed circuit board.

9. The computer assembly of claim 8, wherein a pair of front outriggers of the plurality of outriggers of each surface mount electrical connector overhangs the edge portion of the printed circuit board.

10. The computer assembly of claim 6, wherein each of the plurality of outriggers are on the printed circuit board.

11. The computer assembly of claim 6, wherein the plurality of outriggers comprises a first pair of outriggers at a first side of the housing and a second pair of outriggers at a second side of the housing opposite to the first side, wherein the first pair of outriggers are higher than the second pair of outriggers.

12. The computer assembly of claim 11, wherein the second pair of outriggers are substantially flush with a lower surface of the housing, and wherein the first pair of outriggers are spaced apart from the lower surface of the housing.

13. The computer assembly of claim 6, wherein the plurality of outriggers comprises a first pair of outriggers at a first side of the housing and a second pair of outriggers at a second side of the housing opposite to the first side, wherein the first pair of outriggers are at different heights on the housing, and wherein the second pair of outriggers of the plurality of outriggers are at different heights on the housing.

14. A method of installing a plurality of electrical connectors on a printed circuit board, the method comprising:
positioning a first electrical connector and a second electrical connector of the plurality of electrical connectors on a first side of the printed circuit board and along an edge portion of the printed circuit board, wherein a pair of outriggers of the first electrical connector overlap a pair of outriggers of the second electrical connector;
positioning a third electrical connector and a fourth electrical connector of the plurality of electrical connectors on a second side of the printed circuit board opposite to the first side of the printed circuit board, wherein a pair of outriggers of the third electrical connector overlap a pair of outriggers of the fourth electrical connector; and
compressing a plurality of pads on each of the first electrical connector, the second electrical connector, the third electrical connector, and the fourth electrical connector against a plurality of IO pads on the printed circuit board by inserting fasteners through aligned openings in the pair of outriggers in each of the first electrical connector, the second electrical connector, the third electrical connector, and the fourth electrical connector.

15. The method of claim 14, wherein the pair of outriggers of the first electrical connector are coupled to a first housing and the pair of outriggers of the second electrical connector are coupled to a second housing, and wherein the pair of outriggers of the first electrical connector are higher on the first housing than the pair of outriggers of the second electrical connector are on the second housing.

16. The method of claim 15, wherein the pair of outriggers of the second electrical connector are substantially flush with a lower surface of the second housing, and wherein the pair of outriggers of the first electrical connector are spaced apart from a lower surface of the first housing by a gap.

17. The method of claim 14, wherein the pair of outriggers of the first electrical connector are coupled to a first housing and the pair of outriggers of the second electrical connector are coupled to a second housing, wherein the pair of outriggers of the first electrical connector are at different heights on the first housing, and wherein the pair of outriggers of the second electrical connector are at different heights on the second housing.

18. The method of claim 14, wherein a portion of each of the first electrical connector, the second electrical connector, the third electrical connector, and the fourth electrical connector overhangs the edge portion of the printed circuit board.

19. The method of claim 18, wherein two outriggers of each of the first electrical connector, the second electrical connector, the third electrical connector, and the fourth electrical connector overhang the edge portion of the printed circuit board.

20. The method of claim 14, wherein the pair of outriggers of each of the first electrical connector, the second electrical connector, the third electrical connector, and the fourth electrical connector are on the printed circuit board.
